(19) United States
(12) Patent Application Publication
(10) Pub. No.: US 2007/0230154 A1
(43) Pub. Date: Oct. 4, 2007

(54) Electronic unit and electronic apparatus having the same

(75) Inventor: Noriyasu Nakayama, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/604,697

(22) Filed: Nov. 28, 2006

(30) Foreign Application Priority Data
Mar. 28, 2006 (JP) 2006-088318

(51) Int. Cl. H05K 7/04; H05K 7/02

(52) U.S. Cl. 361/810

(57) ABSTRACT

An electronic unit includes a flexible printed circuit board that is mounted with plural electronic components, and forms a layered structure through folding, and a joint that electrically connects wiring parts on two end surfaces of the flexible printed circuit board, at least two of the plural electronic components being connected so that the at least two can communicate with each other through the wiring parts of the joint.

This application claims the right of foreign priority under 35 U.S.C. §119 based on Japanese Patent Application No. 2006-088318, filed on Mar. 28, 2006, which is hereby incorporated by reference herein in its entirety as if fully set forth herein.

### BACKGROUND OF THE INVENTION

The present invention relates generally to a printed circuit board, and more particularly to an electronic unit that layers plural electronic components using a flexible printed circuit board (“FPC”). The present invention is suitable, for example, for a multi-chip module used for an electronic apparatus, such as a digital camera, a cellular phone, a CCD module, a liquid crystal panel, and a laptop personal computer (“PC”).

A high-performance and small electronic apparatus has recently increasingly demanded. In order to achieve the high performance, the system in package (“SiP”) technology has been developed which is mounted with plural semiconductor chips and enables these chips to communicate each other. However, in order to achieve miniaturization, it is difficult to arrange plural semiconductor chips on the same plane in the electronic apparatus. Accordingly, a multi-chip module has recently been proposed which layers plural chips using the FPC (see, for example, Japanese Patent Applications, Publication Nos. 6-125037 and 11-135715).

FIG. 11 is a schematic sectional view of a multi-chip module 10 disclosed in Japanese Patent Application, Publication No. 6-125037. FIG. 12 is a schematic sectional view of a multi-chip module 10A disclosed in Japanese Patent Application, Publication No. 11-135715. In FIGS. 11 and 12, 12a to 12c denote semiconductor chips connected to a wiring part or wiring pattern (not shown) of an FPC 16. This wiring part extends along the FPC 16, and plural semiconductor chips 12a to 12c can communicate with each other.

Other prior art include Japanese Patent Applications, Publication Nos. 9-181225, 11-112215 and 2001-20319.

However, the multi-chip modules 10 and 10A have such a long wiring length of the wiring part (not shown) for connecting the semiconductor chips 12a and 12c to each other that the interference and delay occur, and pose a problem of a difficult design to meet the proper timing requirement.

### BRIEF SUMMARY OF THE INVENTION

The present invention is directed to an electronic unit that shortens a wiring length among electronic components, and an electronic apparatus having the same.

An electronic unit according to one aspect of the present invention includes a flexible printed circuit board that is mounted with plural electronic components, and forms a layered structure through folding, and a joint that electrically connects wiring parts on two end surfaces of the flexible printed circuit board, at least two of the plural electronic components being connected so that the at least two can communicate with each other through the wiring parts of the joint. This electronic unit, such as a multi-chip module, allows to electronic components, such as semiconductor chips, to communicate with each other via a wiring part or wiring pattern of the joint, shortening a wiring length rather than a communication without intervening the joint.

The flexible printed circuit board may include plural joints that have end surfaces with different widths.

The flexible printed circuit board may have a first part that extends in a first longitudinal direction before the flexible printed circuit board is folded, and a second part that extends in a second longitudinal direction that inclines to the first longitudinal direction before the flexible printed circuit board is folded, and wherein the first part is folded around a line orthogonal to the first longitudinal direction, and the second part is folded around a line orthogonal to the second longitudinal direction. For example, the second longitudinal direction may be orthogonal to the first longitudinal direction or inclined to the first longitudinal direction by 60°. A pair of end surfaces of the joint may be provided to the first and second parts. In other words, the end surface having the wiring part connected to the wiring part on the end surface of the first part is not necessary provided on the first part.

The flexible printed circuit board may form two or more annular members. For example, two annular members include two orthogonal parts, and three annular members include three parts that incline to each other by 60°.

A method according to another aspect of the present invention for manufacturing an electronic unit includes the steps of folding a flexible printed circuit board mounted with plural electronic components, and electrically connecting wiring parts on two end surfaces to each other at a joint on the two end surfaces of the flexible printed circuit board so that two of the plural electronic components can communicate with each other via the wiring parts of the joint. The electronic unit manufactured by this manufacturing method exhibits operations similar to those of the above electronic apparatus.

The electrically connecting step may be performed when a second wiring length is shorter than a first wiring length, the first wiring length being a length when the two electronic components are connected via the joint, and the second wiring length being a length when the two electronic components are connected without intervening the joint.

An electronic apparatus including a circuit board mounted with the electronic unit also constitutes one aspect of the present invention.

Other objects and further features of the present invention will become readily apparent from the following description of preferred embodiments with reference to the accompanying drawings.

### BRIEF DESCRIPTION OF THE DRAWINGS

FIG. 1 is a schematic sectional view of an electronic unit (multi-chip module) according to one embodiment of the present invention.

FIG. 2 is a schematic perspective view of a flexible printed circuit board (“FPC”) shown in FIG. 1 before it is folded.

FIG. 3 is a schematic perspective view of a variation of the FPC shown in FIG. 2 before it is folded.

FIG. 4 is a schematic perspective view of the variation of the FPC shown in FIG. 2 after it is folded.

FIG. 5 is a schematic perspective view of the FPC shown in FIG. 4 before it is folded.

FIG. 6 is a schematic perspective view of a variation of the FPC shown in FIG. 5 before it is folded.

FIG. 7 is a schematic perspective view of another variation of the FPC shown in FIG. 5 before it is folded.

FIG. 8 is a schematic perspective view of still another variation of the FPC shown in FIG. 2 before it is folded.

FIG. 9 is a flowchart for explaining a manufacturing method of an electronic unit according to the present invention.

FIG. 10 is a schematic perspective view of one illustrative electronic apparatus according to the present invention.

FIG. 11 is a schematic partial sectional view of a conventional multi-chip module.

FIG. 12 is a schematic partial sectional view of another conventional multi-chip module.

### DETAILED DESCRIPTION OF THE PREFERRED EMBODIMENTS

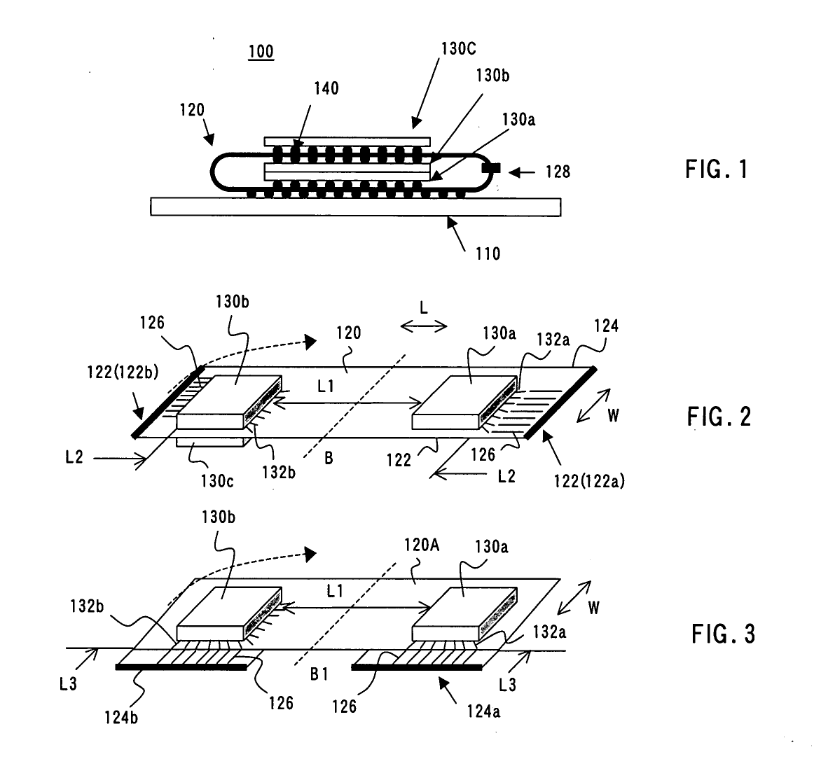

Referring now to the accompanying drawings, a description will be given of an electronic apparatus according to the present invention. This electronic apparatus is implemented as a multi-chip module 100. Here, FIG. 1 is a schematic sectional view of the multi-chip module 100. The multi-chip module 100 is a module mounted with plural bare semiconductor chips called a bare chip on an FPC. The multi-chip module can form a three-dimensional structure that layers chips, saves the area, and has an advantage of using devices that have experienced different manufacturing processes. The multi-chip module 100 includes, as shown in FIG. 1, a base plate 110, an FPC 120, first to third electronic components 130a to 130c, a connection part 140, and a joint 128.

The base plate 110 is, for example, a circuit board, such as a motherboard.

The FPC 120 has a ground layer (not shown) between a pair of insulating layers (not shown), and a wiring part 126 in or on the insulating layer as in Japanese Patent Application, Publication No. 9-181225. A pair of end surfaces are jointed in the FPC 120, as shown in FIG. 1, through folding, bending or curved. The folded FPC 120 forms an annular member as shown in FIG. 1.

FIG. 2 shows the FPC 120 in a development state or before it is folded. Here, FIG. 2 is a schematic perspective view of the FPC 120 in the development stage or before it is folded. The FPC 120 has a band or strap shape that extends in a longitudinal direction L and, has a constant width in a width direction W. The FPC 120 is mounted with the first electronic component 130a at the right side on the front surface, the second electronic component 130b at the left side on the front surface, and the third electronic component 130c below the second electronic component 130b and at the left side on the rear surface. The FPC 120 has a pair of end surfaces 122 at the both sides in the longitudinal or length direction L, and a pair of end surfaces 124 in the traverse or width direction W. In this embodiment, the FPC 120 is bent as shown by a dotted arrow during joining, and joined at its end surfaces 122. The following description may express the right end surface 122 as an end surface 122a and the left end surface 122 as an end surface 122b. In FIG. 2, a notation 122 (122a) etc. mean that 122 generalizes 122a, etc. This notation applies to another reference numeral.

The wiring part 126 exposes on the end surfaces 122 at the joint 128. In FIG. 2, in joining the end surfaces 122a and 122b, the wiring parts 126 are electrically connected. In other words, in FIG. 2, one of the wiring parts 126 that extend from the right side of the first electronic component 130a, and expose on the end surfaces 122a is electrically connected to one of the wiring parts 126 that extend from the left side of the second electronic component 130b, and expose on the end surfaces 122b via soldering (not shown).

Thus, this embodiment enables the first and second electronic components 130a and 130b to communicate with each other via the wiring part 126 that extends across the joint 128. In this case, as shown in FIG. 2, the first and second electronic components 130a and 130b have a wiring length L2. The wiring length L2 is a wiring length between the first and second electronic components 130a and 130b when the first and second electronic components 130a and 130b are connected at the joint 128 (i.e., a distance between a right terminal 132a of the first electronic component 130a and a left terminal (not shown) of the second electronic component 130b). Strictly speaking, a wiring length between them may slightly differ, but this embodiment ignores this difference. Of course, the wiring length L2 may use another distance among the distances between the right terminal 132a of the first electronic component 130a and the left terminal (not shown) of the second electronic component 130b, such as the longest distance, the shortest distance, and an average distance.

Conventionally, there is no joint 128 or joint 128 exits but has only a ground layer as in Japanese Patent Application, Publication No. 9-181225, and the joint 128 does not connect the wiring layer 126. Therefore, the conventional structure does not allow the first and second electronic components 130a and 130b to communicate with each other via the joint 128, and the wiring length between them is kept always L1. Here, the wiring length L1 is a distance between a left terminal (not shown) of the first electronic component 130a and a right terminal 132b of the second electronic component 130b in FIG. 2. Strictly speaking, a wiring length between them may slightly differ, but this embodiment ignores this difference. Of course, the wiring length L1 may use another distance among the distances between the left terminal (not shown) of the first electronic component 130a and the right terminal 132b of the second electronic component 130b, such as the longest distance, the shortest distance, and an average distance.

The conventional structure is feasible when the distance L1 is shorter than the distance L2, but the interference and delay occur when the distance L1 is much longer than the distance L2. Accordingly, this embodiment enables the first and second electronic components 130a and 130b to communicate with each other by a shorter one of the wiring lengths L1 and L2.

This embodiment, when selecting the wiring length L2, provides no wiring part 126 used to connect and arranged between the left terminal (not shown) of the first electronic component 130a and the right terminal 132b of the second electronic component 130b, so as to avoid an unnecessary dual connection between them and the signal interference or delay. In other words, both elements may be connected, for example, when the signal interference and delay are not problematic.

This embodiment addresses only the wiring parts 126, but a ground layer (not shown) may be further connected in the joint 128. While the wiring parts 126 of this embodiment are located in the same layer, the present invention does not prevent the connection of two wiring parts 126 in different layers. Therefore, a connection of the first and second electronic components may be expanded to a connection between other electronic components, such as the first and third electronic components.

While the embodiment shown in FIG. 2 folds the FPC 120 at the time of joining as shown by a dotted arrow and joins the end surfaces 122, the present invention is not limited to the joint on the end surfaces 122 in the longitudinal direction L of the FPC 120.

For example, as shown in FIG. 3, the FPC 120A may be joined via end surfaces 124a and 124b. FIG. 3 omits the third electronic component 130c. In FIG. 3, the first and second components 130a and 130b have a wiring length L3. The wiring length L3 is a distance between a lower terminal 132a of the first electronic component 130a and a lower terminal 132b of the second electronic component 130b. A definition of the wiring length L3 is similar to those of the wring lengths L1 and L2.

Although a folding line B shown by a broken line of the FPC 120 is parallel to the end surface 122 or the side of the joint 128 in FIG. 2, a folding line B1 shown by a broken line is perpendicular to the end surfaces 124a and 124b in FIG. 3. In addition, although the end surfaces 122a and 122b oppose to each other in the joint 128 in FIG. 2, the end surfaces 124a and 124b do not oppose to each other in FIG. 3.

In FIGS. 2 and 3, the joint includes only a pair of end surfaces, but the joint may include two or more sides. In principle, the joint contains the wiring part. For example, FIG. 3 connects only the lower terminals 132a and 132b to each other. When the upper terminals (not shown) have approximately the same wiring lengths, they may be connected to increase the design freedom. When plural joints are provided, one joint may contain only the ground layer if necessary.

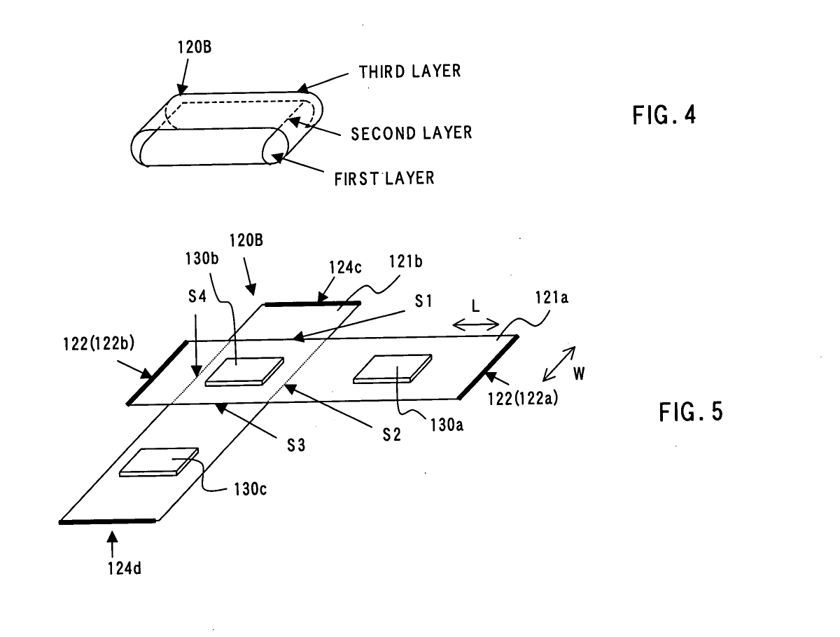

The shape of the FPC 120 of this embodiment is not limited to the band shape shown in FIG. 2. For example, as shown in FIGS. 4 and 5, an FPC 120B having an overlap shape of two orthogonal bands may be used. FIG. 4 is a schematic perspective view of the FPC 120B after the FPC 120B is folded. FIG. 5 is a schematic perspective view of the FPC 120B before the FPC 120B is folded. FIG. 5 omits the wiring part 126 for simplicity.

The FPC 120B includes two parts 121a and 121b, and is mounted with the first to third electronic components 130a to 130c. The part 121a corresponds to the FPC 120 shown in FIG. 2, and the longitudinal directions of the parts 121a and 121b form 90°. The FPC 120B has two joints. The first joint joins the end surfaces 122a and 122b of the first part 121a. The second part joins the end surfaces 124c and 124d of the second part 121b. These end surfaces have the same width, but the present invention is not limited to this embodiment as described with reference to FIG. 7. This arrangement forms the three-layer structure shown in FIG. 4 or two annular members. Sides S2 and S3 are alternately bent and form the second and third layers. Sides S1 to S4 function as a folding line.

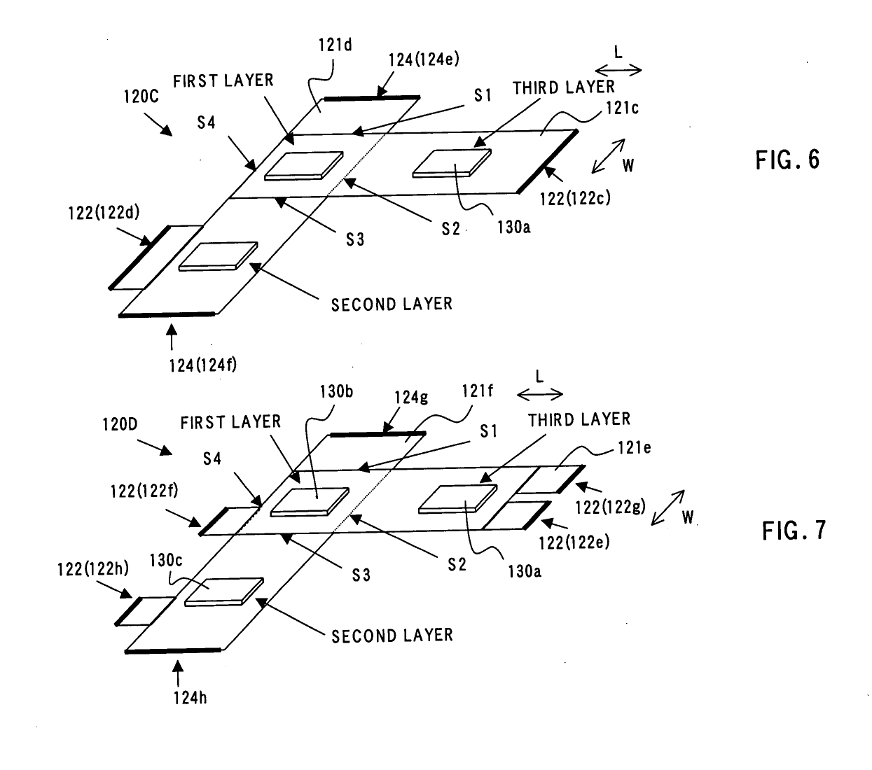

FIG. 6 is a schematic perspective view of the FPC 120C as a variation of FIG. 5. FIG. 6 omits the wiring part 126 for simplicity. The FPC 120C has two parts 121c and 121d, and is mounted with the first to third electronic components 130a to 130c. The longitudinal directions of the parts 121c and 121d form 90°. Different from FIG. 5, the parts 121c and 121d do not have the same shape. The FPC 120C has two joints. The first joint joins the end surfaces 122c and 122d of the first part 121c. The second part joins the end surfaces 124e and 124f of the second part 121d.

FIG. 6 replaces the end surface 122b shown in FIG. 5 with the end surface 122d. In other words, the first part 121c has only one end surface 122c that forms the joint, and the second part 121d has three end surfaces 122d, 124e, and 124f that form the joints. Thus, each part (121c, 121d) of the FPC does not necessary have a pair of end surfaces that form the joint, or may have an end surface that forms another part's joint.

In FIG. 6, the end surfaces 124e and 124f are electrically joined by folding the side S3, and the first annular structure is formed. Thereafter, the third layer is formed by folding the side S2. Thereafter, the end surfaces 122c and 122d of the second layer and third layer are joined to form the second annular structure.

FIG. 7 is a schematic perspective view of the FPC 120D as another variation of FIG. 5. FIG. 7 omits the wiring part 126 for simplicity. The FPC 120D has two parts 121e and 121f, and is mounted with the first to third electronic components 130a to 130c. The longitudinal directions of the parts 121e and 121f form 90°. Different from FIG. 5, the parts 121e and 121f do not have the same shape. The FPC 120D has three joints. The first joint joins the end surfaces 122e and 122f of the first part 121e. The second part joins the end surface 122g of the first part 121e and the end surface 122h of the second part 121f. The third part joins the end surfaces 124g and 124h of the second part 121f.

FIG. 7 divides the end surfaces 122a and 122c into two end surfaces 122e and 122g. The first part 121e has three end surfaces 122e to 122g. The second part 121f has three end surfaces 122h, 124g, and 124h. The end surfaces 122e and 124g have different lengths. As shown in the end surfaces 122e and 122g. By diving one side into plural sub-sides, the first layer and the third layer, and the second layer and the third layer can be joined at the side S4.

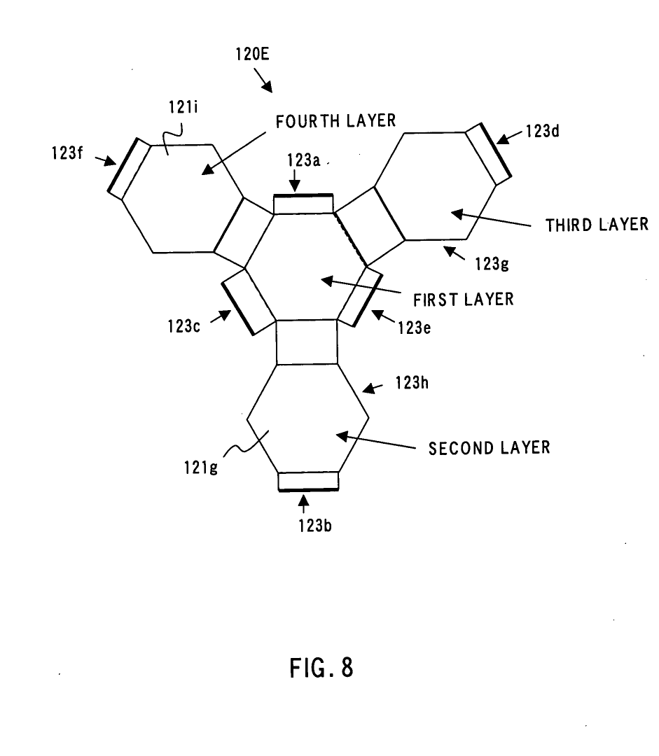

The FPC has two parts in FIGS. 5 to 7, but the FPC may have three or more parts. FIG. 8 is a schematic perspective view of the FPC 120E having three parts 121g to 121i. The three parts 121g to 121i form 60°. Of course, the present invention is applicable to an FPC having four or more parts. The part 121g has end surfaces 123a and 123e. The part 121h has end surfaces 123c and 123d. The part 121i has end surfaces 123e and 123f. Each part has a pair of end surfaces to be paired for the three joints, but the paired end surface may be arranged at another part or divided similar to FIGS. 5 to 7.

Moreover, FIGS. 5 to 7 show a three-layer structure, but FIG. 8 shows a four-layer structure. Thus, the present invention does not limit the number of layers. In folding, first, the second layer part is folded, and the end surfaces 123a and 123b are electrically connected. Next, the third layer part is folded to cover the second layer, and the end surfaces 123c and 123d are electrically connected. Moreover, the fourth layer part is folded to cover the third layer part, and end surfaces 123e and 123f are electrically connected. Thereby, three annular structures or four-layer structure can be formed.

Since two sides are connected in the hexagon on or above the second layer, the second and third layers can be directly connected by electrically connecting the end surfaces 123g and 123h shown in FIG. 8 to each other.

The first to third electronic components 130a to 130c are, for example, semiconductor chips. The bump or pad 140 is a connection part that connects each electronic component to the FPC 120.

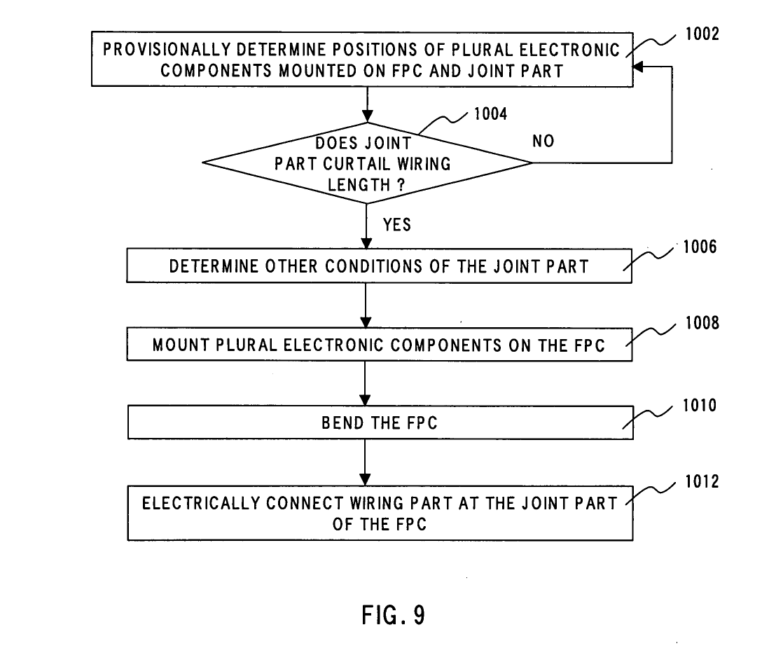

Referring now to FIG. 9, a description will be given of a manufacturing method of an electronic apparatus according to the present invention. First, positions of plural electronic components mounted on the FPC 120 and joints are provisionally determined in the design (step 1002). In the joint, the wiring parts of a pair of end surfaces are joined so that two electronic components can communicate with each other. In principle, the position of the joint is determined as described with reference to FIG. 2 so that the wiring length L2 is shorter than the wiring length L1, where the wiring length L2 is a length when the two electronic components 130a and 130b are connected via the joint 128, and the wiring length L1 is a length when the two electronic components 130a and 130b are connected without intervening the joint 128. It is determined whether the joint shortens the wiring length (step 1004). If so, any other conditions of the joint are determined (step 1006) (e.g., whether to divide, whether to provide to another part, whether to provide plural joints when there are approximately the same wiring length). When the joint does not shorten the wiring length in step 1004, the procedure is fed back to step 1002 for a determination using another joint.

In manufacturing, plural electronic components are mounted on the FPC 120 (step 1008). Next, the FPC 120 is folded (step 1010). Next, the wiring parts 126 are electrically connected at the joint 128 of the FPC 120 (step 1012). This manufacturing method produces an electronic unit having a short wiring length with little signal interference and delay.

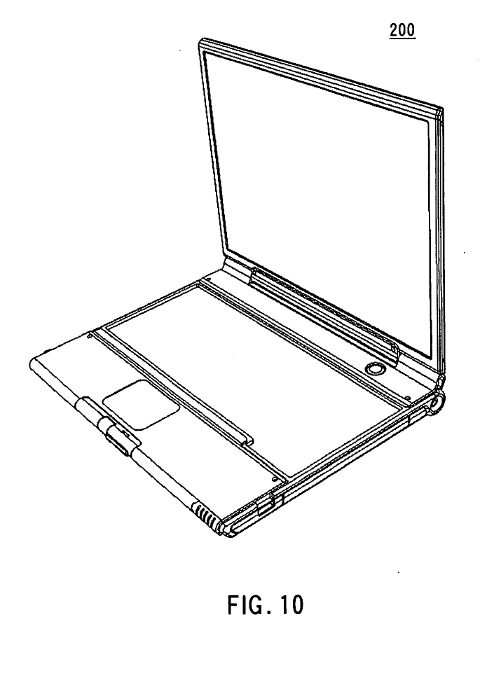

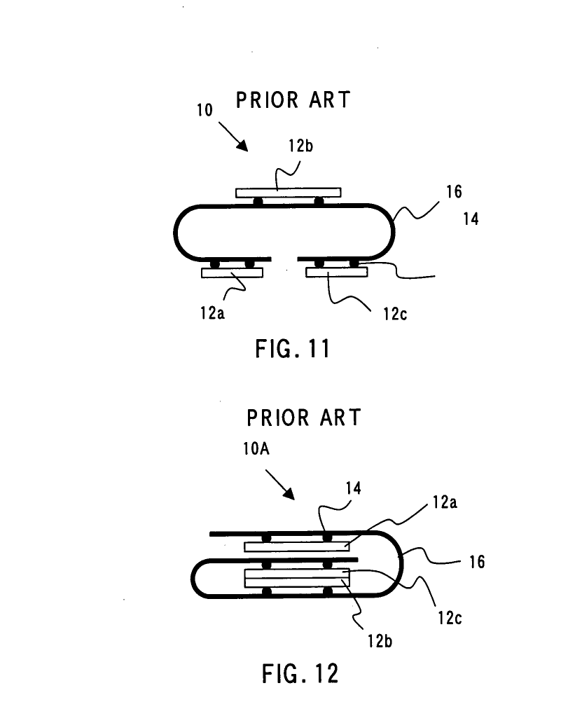

A description will now be given of an electronic apparatus to which the electronic unit 100 of the present invention is applicable. The present invention is not limited to the type of electronic apparatus as long as a miniaturization is sought. The electronic apparatus is, for example, a digital camera, a cellular phone, a CCD module, a liquid crystal panel, a laptop PC, etc. FIG. 10 is a schematic perspective view of the laptop PC 200. The inventive multi-chip module is suitable, for example, for the CPU of the laptop PC 200.

Further, the present invention is not limited to these preferred embodiments, and various variations and modifications may be made without departing from the scope of the present invention.

The present invention is directed to an electronic unit that shortens a wiring length among the electronic components and an electronic apparatus having the same.

What is claimed is:

1. An electronic unit comprising:
a flexible printed circuit board that is mounted with plural electronic components, and forms a layered structure through folding; and
a joint that electrically connects wiring parts on two end surfaces of said flexible printed circuit board, at least two of the plural electronic components being connected so that the at least two can communicate with each other through the wiring parts of the joint.

2. An electronic unit according to claim 1, wherein said flexible printed circuit board includes plural joints that have end surfaces with different widths.

3. An electronic unit according to claim 1, wherein said flexible printed circuit board has a first part that extends in a first longitudinal direction before said flexible printed circuit board is folded, and a second part that extends in a second longitudinal direction that inclines to the first longitudinal direction before said flexible printed circuit board is folded, and
wherein the first part is folded around a line orthogonal to the first longitudinal direction, and the second part is folded around a line orthogonal to the second longitudinal direction.

4. An electronic unit according to claim 3, wherein a pair of end surfaces of the joint are provided to the first and second parts.

5. An electronic unit according to claim 1, wherein said flexible printed circuit board forms two or more annular members.

6. A method for manufacturing an electronic unit, said method comprising the steps of:
folding a flexible printed circuit board mounted with plural electronic components; and
electrically connecting wiring parts on two end surfaces to each other at a joint on the two end surfaces of the flexible printed circuit board so that two of the plural electronic components can communicate with each other via the wiring parts of the joint.

7. A method according to claim 6, wherein said electrically connecting step is performed when a second wiring length is shorter than a first wiring length, the first wiring length being a length when the two electronic components are connected via the joint, and the second wiring length being a length when the two electronic components are connected without intervening the joint.

8. An electronic apparatus comprising a circuit board mounted with an electronic unit according to claim 1.
